(19) United States
(12) Patent Application Publication
(10) Pub. No.: US 2024/0113208 A1
(43) Pub. Date: Apr. 4, 2024

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Kohei SAKO, Tokyo (JP); Yuji EBIIKE, Tokyo (JP); Kazuya INOUE, Tokyo (JP)

(73) Assignee: Mitsubishi Electric Corporation, Tokyo (JP)

(21) Appl. No.: 18/180,716

(22) Filed: Mar. 8, 2023

(30) Foreign Application Priority Data
Sep. 29, 2022 (JP) 2022-156707

(51) Int. Cl. H01L 29/739; H01L 29/40; H01L 29/423; H01L 29/66

(52) U.S. Cl. CPC H01L 29/7397; H01L 29/407; H01L 29/4236; H01L 29/66348

(57) ABSTRACT

A semiconductor device according to an aspect of the present disclosure, includes a semiconductor layer in which a trench is formed, a buried electrode provided inside the trench, an upper electrode provided above the buried electrode inside the trench, an insulating film provided inside the trench, a first electrode provided on an upper surface of the semiconductor layer, and a second electrode provided on a lower surface of the semiconductor layer, wherein the insulating film includes a first portion between the buried electrode and a side wall of the trench, a second portion between the upper electrode and the side wall of the trench, and a third portion between the buried electrode and the upper electrode, and a lower surface of the upper electrode has a dent in a central portion.

### BACKGROUND

### Field

The present disclosure relates to a semiconductor device and a method for manufacturing the semiconductor device.

### Background

In a method for manufacturing a semiconductor device in JP 2013-175596 A, a first insulating film that covers an inner surface of a trench formed in a semiconductor layer, and a second insulating film laminated on the first insulating film are formed. Then, a first control electrode facing the semiconductor layer via the first insulating film and the second insulating film is formed in a lower portion of the trench. Then, a third insulating film is formed on the first control electrode. Then, the first insulating film and the second insulating film formed on a wall surface in an upper portion of the trench are removed, and a fourth insulating film is formed. In the upper portion of the trench, a second control electrode facing the semiconductor layer via the fourth insulating film and facing the first control electrode via the third insulating film is formed.

In the semiconductor device of JP 2013-175596 A, part of the insulating film inside the trench acts as an insulating film between a gate and a collector. However, if the insulating film is made thicker, a threshold voltage increases. Thus, the insulating film cannot be made thicker, which may make it impossible to reduce gate-collector capacitance.

### SUMMARY

An object of the present disclosure, which has been made to solve the above-described problem, is to provide a semiconductor device in which capacitance can be reduced, and a method for manufacturing the semiconductor device.

The features and advantages of the present disclosure may be summarized as follows.

According to an aspect of the present disclosure, a semiconductor device includes a semiconductor layer in which a trench is formed, a buried electrode provided inside the trench, an upper electrode provided above the buried electrode inside the trench, an insulating film provided inside the trench, a first electrode provided on an upper surface of the semiconductor layer, and a second electrode provided on a lower surface of the semiconductor layer, wherein the insulating film includes a first portion between the buried electrode and a side wall of the trench, a second portion between the upper electrode and the side wall of the trench, and a third portion between the buried electrode and the upper electrode, and a lower surface of the upper electrode has a dent in a central portion.

According to an aspect of the present disclosure, a method for manufacturing a semiconductor device includes forming a trench in a semiconductor layer, forming a buried electrode and a first oxide film that separates the buried electrode from a side wall of the trench, inside the trench, removing part of the first oxide film so that a portion above the buried electrode, among the first oxide film, has a tapered shape, forming a second oxide film so as to cover an upper surface of the buried electrode, the side wall of the trench and the portion having the tapered shape; and forming an upper electrode on the second oxide film inside the trench.

Other and further objects, features and advantages of the disclosure will appear more fully from the following description.

### BRIEF DESCRIPTION OF DRAWINGS

FIG. 1 is a cross-sectional view of a semiconductor device according to a first embodiment.

FIGS. 2 to 15 are views illustrating a method for manufacturing the semiconductor device according to the first embodiment.

FIG. 16 is a cross-sectional view of a semiconductor device according to a second embodiment.

FIG. 17 is an enlarged view of a cross-section of a semiconductor device according to a third embodiment.

### DESCRIPTION OF EMBODIMENTS

A semiconductor device and a method for manufacturing the semiconductor device according to each embodiment will be described with reference to the accompanying drawings. Components identical or corresponding to each other are indicated by the same reference characters, and repeated description of them is avoided in some cases.

### First Embodiment

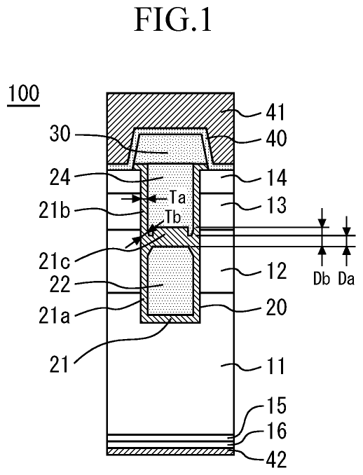

FIG. 1 is a cross-sectional view of a semiconductor device 100 according to a first embodiment. The semiconductor device 100 is, for example, an insulated gate bipolar transistor (IGBT) having a trench gate structure. In the semiconductor device 100, an n-type carrier accumulation layer 12 is formed on an n-type drift layer 11. On the n-type carrier accumulation layer 12, a p-type base layer 13 and an n-type emitter layer 14 are formed in this order. An n-type buffer layer 15 and a p-type collector layer 16 are formed under the n-type drift layer 11.

The n-type drift layer 11, the n-type carrier accumulation layer 12, the p-type base layer 13, the n-type emitter layer 14, the n-type buffer layer 15 and the p-type collector layer 16 correspond to a semiconductor layer. Further, the n-type corresponds to a first conductive type, and the p-type corresponds to a second conductive type different from the first conductive type. The conductive types of the layers may be reverse. The n-type drift layer 11 and the n-type carrier accumulation layer 12 correspond to a first semiconductor layer, and the p-type base layer 13 corresponds to a second semiconductor layer.

A trench 20 is formed in the semiconductor layer. Two electrodes: a buried electrode 22 and an upper electrode 24 are provided inside the trench 20. The upper electrode 24 is provided over the buried electrode 22. Further, an insulating film 21 is provided inside the trench 20. The insulating film 21 includes a first portion 21a between the buried electrode 22 and a side wall of the trench 20, a second portion 21b between the upper electrode 24 and the side wall of the trench 20, and a third portion 21c between the buried electrode 22 and the upper electrode 24. In other words, the first portion 21a separates the buried electrode 22 and the semiconductor layer. The second portion 21b separates the upper electrode 24 and the semiconductor layer. The third portion 21c separates the buried electrode 22 and the upper electrode 24.

The upper electrode 24 includes at a lower end, a portion in which a side surface is inclined inward of the trench 20. By this means, the second portion 21b of the insulating film 21 is formed thicker downward. Further, a lower surface of the upper electrode 24 has a dent in a central portion.

A barrier metal 40 and an emitter electrode 41 that is a main electrode are provided on an upper surface of the semiconductor layer. An interlayer dielectric 30 separates the upper electrode 24 and the emitter electrode 41. A collector electrode 42 that is a main electrode is provided on a lower surface of the semiconductor layer. The emitter electrode 41 corresponds to a first electrode, and the collector electrode 42 corresponds to a second electrode.

The upper electrode 24 is connected to a gate potential, and the buried electrode 22 is connected to an emitter potential. This shields the upper electrode 24, so that it is possible to reduce gate-collector capacitance. Further, if a thickness Ta of the second portion 21b of the insulating film 21 is made thicker, the gate-collector capacitance can be further reduced. However, making the insulating film 21 thicker leads to increase of a threshold voltage. The threshold voltage is basic characteristics of the semiconductor device 100. If the threshold voltage increases, there is a possibility that other characteristics such as a saturated current may degrade. Thus, making the second portion 21b thicker is generally not allowed.

In contrast, in the present embodiment, the second portion 21b of the insulating film 21 is formed thicker downward. In other words, Ta<Tb. This makes it possible to reduce gate-collector capacitance while preventing increase of the threshold voltage. Particularly, capacitance between the upper electrode 24 and the n-type carrier accumulation layer 12 is likely to contribute to the gate-collector capacitance. In the present embodiment, for example, among the second portion 21b of the insulating film 21, a portion adjacent to the n-type carrier accumulation layer 12 is thicker than a portion adjacent to the p-type base layer 13. This makes it possible to effectively reduce the gate-collector capacitance while preventing increase of the threshold voltage.

Further, as a result of the third portion 21c of the insulating film 21 being thick, gate-emitter capacitance can be reduced. However, if the third portion 21c is formed thick, there is a possibility that a lower end of the upper electrode 24 may be located above a bottom portion of the p-type base layer 13. In this case, if the insulating film 21 is thick, there is a possibility that the semiconductor device 100 may not operate as a result of a channel being not formed.

In contrast, in the present embodiment, the lower surface of the upper electrode 24 has a dent in the central portion. In other words, in the third portion 21c of the insulating film 21, a thickness Db of the central portion of the trench 20 is thicker than a thickness Da on the semiconductor layer side. According to this configuration, it is possible to secure a thick portion of the third portion 21c while preventing a channel from being unformed. It is therefore possible to reduce the gate-emitter capacitance.

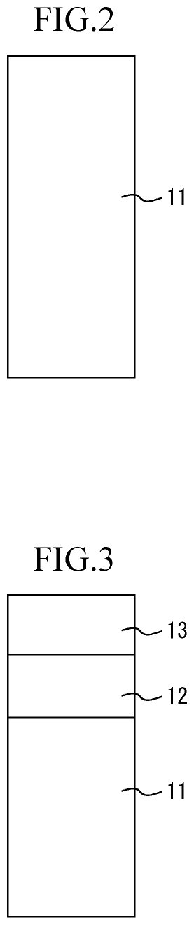

A method for manufacturing the semiconductor device 100 will be described. FIGS. 2 to 15 are views illustrating a method for manufacturing the semiconductor device 100 according to the first embodiment. First, as illustrated in FIG. 2, a semiconductor substrate constituted with the n-type drift layer 11 is prepared. The semiconductor substrate is, for example, a so-called floating zone (FZ) wafer manufactured using a FZ method. The semiconductor substrate may be a so-called magnetic applied Czochralki (MCZ) wafer manufactured using a MCZ method. The semiconductor substrate may be an n-type wafer containing n-type impurities.

Concentration of the n-type impurities contained in the semiconductor substrate is selected as appropriate in accordance with a withstand voltage of the semiconductor device 100 to be manufactured. For example, in the semiconductor device 100 with a withstand voltage of 1200 V, the concentration of the n-type impurities is adjusted so that specific resistance of the n-type drift layer 11 becomes approximately 40 to 120 Ω·cm. As illustrated in FIG. 2, in a process of preparing the semiconductor substrate, the whole of the semiconductor substrate is the n-type drift layer 11. P-type or n-type impurity ions are implanted from a first principal surface side or a second principal surface side of such a semiconductor substrate, and thereafter, the impurity ions are diffused within the semiconductor substrate through heat treatment, or the like. The semiconductor device 100 is manufactured by forming a p-type or n-type semiconductor layer in this manner.

Then, as illustrated in FIG. 3, n-type impurities such as phosphorus (P) are implanted from the first principal surface side of the semiconductor substrate to form the n-type carrier accumulation layer 12. Further, p-type impurities such as boron (B) are implanted from the first principal surface side of the semiconductor substrate to form the p-type base layer 13. The n-type carrier accumulation layer 12 and the p-type base layer 13 are formed by, after implanting impurity ions to the semiconductor substrate, diffusing the impurity ions through heat treatment. The n-type impurity ions and the p-type impurity ions are implanted after the first principal surface of the semiconductor substrate is subjected to mask processing, and thus, the n-type carrier accumulation layer 12 and the p-type base layer 13 are selectively formed on the first principal surface side of the semiconductor substrate. Note that in the mask processing, resist is applied on the semiconductor substrate, and an opening is formed in a predetermined region of the resist using photolithography. Ions are implanted, or etching is applied in the predetermined region of the semiconductor substrate through this opening.

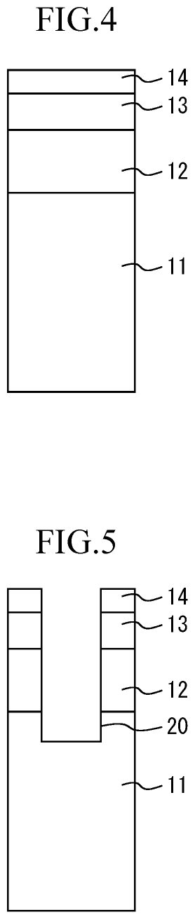

Then, as illustrated in FIG. 4, n-type impurities are selectively implanted on the first principal surface side of the p-type base layer 13 through mask processing to form the n-type emitter layer 14. The n-type impurities to be implanted are, for example, arsenic (As) or phosphorus (P). Further, by p-type impurities being selectively implanted on the first principal surface side of the p-type base layer 13 through mask processing, a p-type contact layer can be formed. In FIG. 4, the p-type contact layer is omitted. The p-type impurities to be implanted are, for example, boron (B) or aluminum (Al).

Then, as illustrated in FIG. 5, the trench 20 is formed in the semiconductor layer. The trench 20 penetrates through the n-type emitter layer 14, the p-type base layer 13 and the n-type carrier accumulation layer 12 from the first principal surface side of the semiconductor layer and reaches the n-type drift layer 11. As a method for forming the trench 20, for example, after an oxide film such as SiO2 is deposited on the semiconductor substrate, an opening is formed in the oxide film at a portion where the trench 20 is to be formed, through mask processing. Then, it is only necessary to form the trench 20 by etching the semiconductor substrate using the oxide film with the opening formed as a mask. A pitch and a pattern in planar view of the trench 20 can be changed as appropriate by a mask pattern of the mask processing.

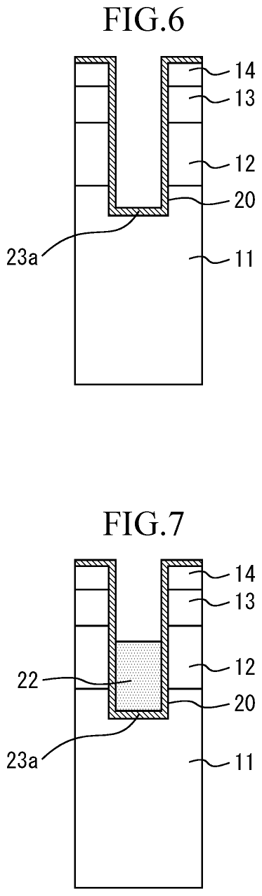

Then, as illustrated in FIG. 6, the semiconductor substrate is heated in an atmosphere including oxygen to form a first oxide film 23a on an inner wall of the trench 20 and the first principal surface of the semiconductor substrate. Then, as illustrated in FIG. 7, polycrystalline silicon doped with n-type or p-type impurities is deposited inside the trench 20 in which the first oxide film 23a is formed on the inner wall through chemical vapor deposition (CVD), or the like. By this means, the buried electrode 22 is formed in a lower portion of the trench 20. As the buried electrode 22, for example, amorphous silicon doped with n-type or p-type impurities may be used instead of polycrystalline silicon. Use of amorphous silicon provides an effect of reducing irregularities on an upper surface of the buried electrode 22. As a result, the buried electrode 22, and the first oxide film 23a that separates the buried electrode 22 from the side wall of the trench 20 are formed inside the trench 20.

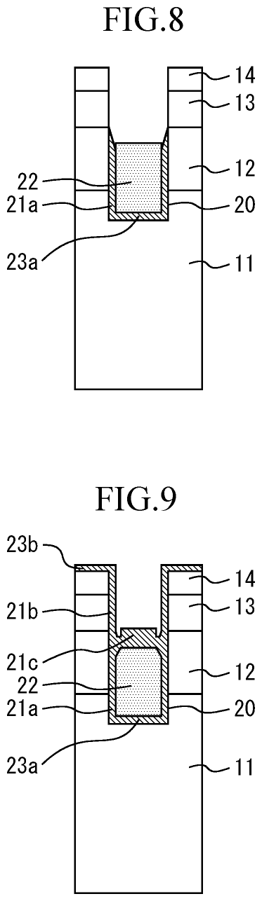

Then, as illustrated in FIG. 8, the first oxide film 23a in an upper portion of the trench 20 and on the first principal surface of the semiconductor substrate is removed through wet etching. By this means, the first portion 21a of the insulating film 21 that separates the buried electrode 22 and the semiconductor layer is formed. The insulating film 21 has characteristics that a portion above the buried electrode 22 is left in a tapered shape. In other words, in the present process, part of the first oxide film 23a is removed so that the portion above the buried electrode 22, among the first oxide film 23a, has a tapered shape.

Then, as illustrated in FIG. 9, the second oxide film 23b is formed so as to cover the first principal surface of the semiconductor substrate, an upper surface of the buried electrode 22, the side wall of the trench 20, and the portion having the tapered shape of the first oxide film 23a. The second oxide film 23b is formed by, for example, heating the semiconductor substrate in an atmosphere including oxygen. As a result of the second oxide film 23b being further formed on the portion having the tapered shape of the first oxide film 23a, a portion that becomes thicker downward is formed in the second portion 21b of the insulating film 21. In this manner, a portion between the upper electrode 24 and the side wall of the trench 20, among the second oxide film 23b, is formed thicker downward.

Further, the buried electrode 22 is polycrystalline silicon doped with impurities, and thus, oxidation is enhanced when the second oxide film 23b is formed. Thus, the second oxide film 23b formed on the upper surface of the buried electrode 22 becomes thicker than the second oxide film 23b formed on the side wall of the trench 20. In other words, the third portion 21c of the insulating film 21 is formed thicker than the second portion 21b.

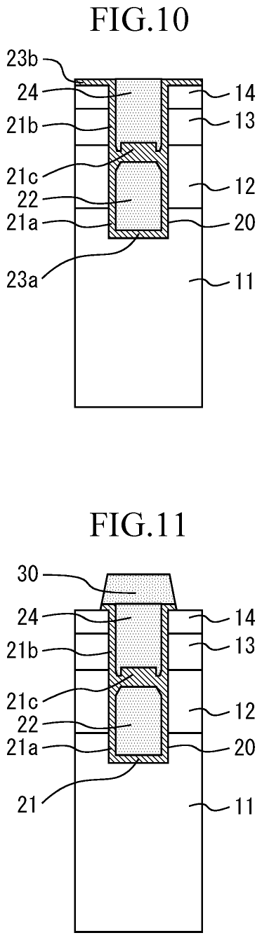

Then, as illustrated in FIG. 10, polycrystalline silicon doped with n-type or p-type impurities is deposited inside the trench 20 through chemical vapor deposition (CVD), or the like. By this means, the upper electrode 24 is formed on the second oxide film 23b inside the trench 20. As the upper electrode 24, for example, amorphous silicon doped with n-type or p-type impurities may be used instead of polycrystalline silicon. However, it is considered that the characteristics are less affected by the irregularities on the upper surface of the upper electrode 24. Thus, use of polycrystalline silicon with a high deposition rate as the upper electrode 24 is efficient in terms of production.

Then, as illustrated in FIG. 11, the interlayer dielectric 30 is deposited on the first principal surface of the semiconductor substrate. Then, the second oxide film 23b formed on the first principal surface of the semiconductor substrate is removed. The interlayer dielectric 30 is, for example, SiO2. Then, a contact hole is formed in the interlayer dielectric 30 through mask processing. The contact hole is formed on the n-type emitter layer 14 and a p-type contact layer (not illustrated).

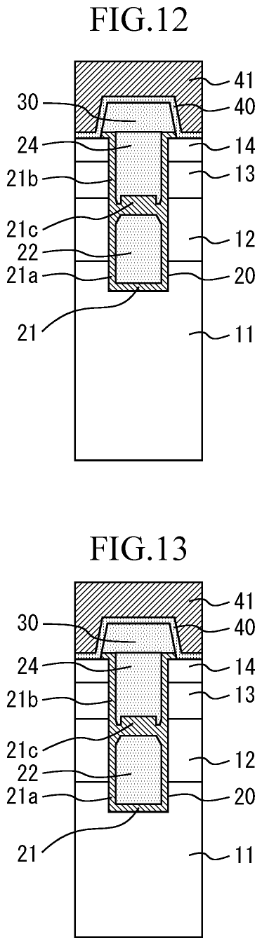

Then, as illustrated in FIG. 12, the barrier metal 40 is formed on the first principal surface of the semiconductor substrate and the interlayer dielectric 30. Further, the emitter electrode 41 is formed on the barrier metal 40. The barrier metal 40 is formed by, for example, depositing of titanium nitride through physical vapor deposition (PVD) or CVD. The emitter electrode 41 is formed by, for example, depositing an aluminum silicon alloy (Al—Si alloy) on the barrier metal through PVD such as sputtering and vapor deposition.

Further, a nickel alloy (Ni alloy) may be further formed on the aluminum silicon alloy through non-electrolytic plating or electrolytic plating to form the emitter electrode 41. By forming the emitter electrode 41 through plating, a thick metal film can be easily formed as the emitter electrode 41. This can increase heat capacity of the emitter electrode 41 thereby improving heat resistance. Note that in a case where after the emitter electrode 41 made of the aluminum silicon alloy is formed through PVD, a nickel alloy is further formed through plate processing, plate processing for forming the nickel alloy may be performed after processing on a second principal surface side of the semiconductor substrate is performed.

Then, as illustrated in FIG. 13, the second principal surface side of the semiconductor substrate is ground to make a thickness of the semiconductor substrate thinner to a predetermined designed thickness. The thickness of the ground semiconductor substrate is, for example, 60 μm to 200 μm.

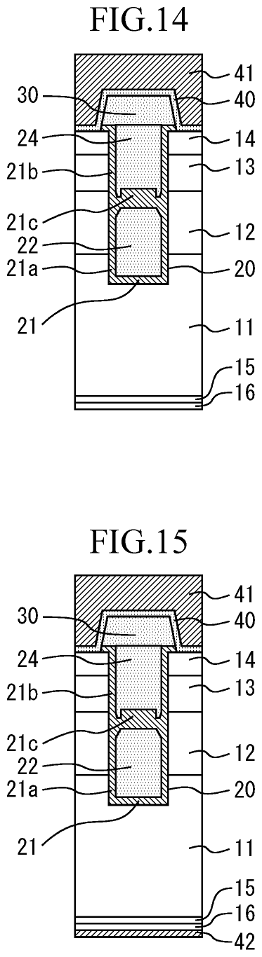

Then, as illustrated in FIG. 14, n-type impurities are implanted from the second principal surface side of the semiconductor substrate to form the n-type buffer layer 15. Further, p-type impurities are implanted from the second principal surface side of the semiconductor substrate to form the p-type collector layer 16. The n-type buffer layer 15 is formed by, for example, implanting phosphorus (P) ions or proton (H+). The n-type buffer layer 15 may be formed by implanting both proton and phosphorus. Proton can be implanted to a deep position from the second principal surface of the semiconductor substrate with low acceleration energy. Further, a depth at which proton is implanted can be easily changed by changing the acceleration energy. Thus, by implanting proton a plurality of times while changing the acceleration energy, it is possible to form the n-type buffer layer 15 that is wider in a thickness direction of the semiconductor substrate than the n-type buffer layer 15 formed of phosphorus.

Further, compared to proton, phosphorus can increase an activation rate as n-type impurities. By forming the n-type buffer layer 15 with phosphorus, even if the semiconductor substrate is made thinner, it is possible to reliably prevent a depletion layer from punching through. To make the semiconductor substrate further thinner, it is preferable to form the n-type buffer layer 15 by implanting both proton and phosphorus. In this event, proton is implanted to a position deeper from the second principal surface than a position of phosphorus.

The p-type collector layer 16 is, for example, formed by implanting boron (B). After ions are implanted from the second principal surface side of the semiconductor substrate, the second principal surface is irradiated with laser to perform laser annealing. By this means, the implanted boron is activated, thereby the p-type collector layer 16 is formed. In this event, phosphorus in the n-type buffer layer 15 implanted to a shallow position from the second principal surface of the semiconductor substrate is also activated at the same time. On the other hand, proton is activated at a relatively low anneal temperature from 350° C. to 500° C. Thus, after proton is implanted, it is necessary to pay attention so that a temperature of the whole of the semiconductor substrate does not become higher than 350° C. to 500° C. in processes other than a process for activating proton. According to laser annealing, it is possible to make a temperature of only a portion near the second principal surface of the semiconductor substrate higher. Thus, even after proton is implanted, laser annealing can be used to activate n-type impurities or p-type impurities.

Then, as illustrated in FIG. 15, the collector electrode 42 is formed on the second principal surface of the semiconductor substrate. The collector electrode 42 is formed by, for example, depositing an aluminum silicon alloy (Al—Si alloy), titanium (Ti), or the like, through PVD such as sputtering and vapor deposition. The collector electrode 42 may be formed by depositing a plurality of metals such as an aluminum silicon alloy, titanium, nickel, and gold. Further, a metal film is further formed through non-electrolytic plating or electrolytic plating on the metal film that is formed through PVD, to form the collector electrode 42.

The semiconductor device 100 is manufactured through the processes as described above. A plurality of the semiconductor devices 100 are manufactured on one n-type wafer in a matrix. The semiconductor device 100 is completed by cutting the wafer into individual semiconductor devices 100 through laser dicing or blade dicing.

As a modification of the present embodiment, if the second portion 21b of the insulating film 21 is formed thicker downward, the lower surface of the upper electrode 24 does not have to have a dent in the central portion. Also in this case, the gate-collector capacitance can be reduced. Further, if the lower surface of the upper electrode 24 has a dent in the central portion, the second portion 21b of the insulating film 21 does not have to be formed thicker downward. Also in this case, the gate-emitter capacitance can be reduced. Further, a material, a shape and a manufacturing method of each layer are not limited to those described above.

The semiconductor layer may be made with a wide band gap semiconductor. The wide band gap semiconductor is silicon carbide, a gallium nitride material or diamond. According to the present embodiment, the gate-collector capacitance can be reduced while preventing increase of the threshold voltage, so that it is possible to effectively utilize performance of the semiconductor device 100 made with the wide band gap semiconductor.

These modifications can be appropriately applied to semiconductor devices and methods for manufacturing the semiconductor devices according to embodiments below. Meanwhile, for the semiconductor devices and the methods for manufacturing the semiconductor devices according to the embodiments below, dissimilarities with the first embodiment will mainly be explained as they have many similarities with the first embodiment.

### Second Embodiment

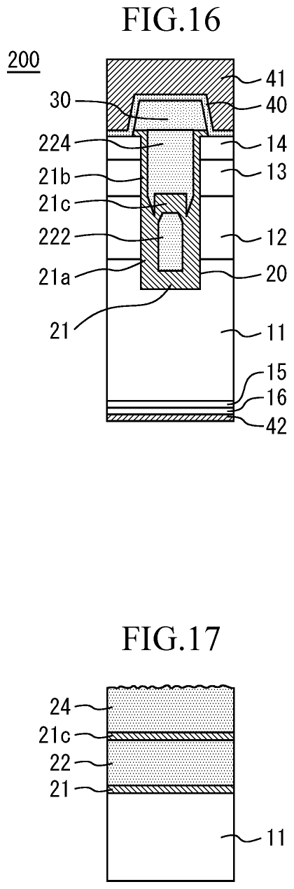

FIG. 16 is a cross-sectional view of a semiconductor device 200 according to a second embodiment. In the present embodiment, structures of the insulating film 21, a buried electrode 222 and an upper electrode 224 are different from the structures in the first embodiment. Other structures are similar to the structures in the first embodiment. In the present embodiment, the first portion 21a of the insulating film 21 is thicker than the second portion 21b. This can make the thickness of the insulating film 21 between the upper electrode 224 and the n-type carrier accumulation layer 12 that largely affects the gate-collector capacitance, further thicker. Thus, the gate-collector capacitance can be further reduced.

### Third Embodiment

FIG. 17 is an enlarged view of a cross-section of a semiconductor device according to a third embodiment. In the present embodiment, irregularities on the upper surface of the buried electrode 22 are smaller than irregularities on the upper surface of the upper electrode 24. This can prevent the third portion 21c of the insulating film 21 from becoming locally thin. It is therefore possible to prevent the gate-emitter capacitance from locally increasing, so that it is possible to improve an effect of reducing the gate-emitter capacitance. By using amorphous silicon doped with n-type or p-type impurities as the buried electrode 22, it is possible to reduce irregularities on the upper surface of the buried electrode 22.

Meanwhile, technical features explained in each embodiment may be appropriately combined to use.

Hereinafter, various aspects of the present disclosure will be collectively described as appendixes.

### (Appendix 1)

A semiconductor device comprising:
a semiconductor layer in which a trench is formed;
a buried electrode provided inside the trench;
an upper electrode provided above the buried electrode inside the trench;
an insulating film provided inside the trench;
a first electrode provided on an upper surface of the semiconductor layer; and
a second electrode provided on a lower surface of the semiconductor layer,
wherein the insulating film includes a first portion between the buried electrode and a side wall of the trench, a second portion between the upper electrode and the side wall of the trench, and a third portion between the buried electrode and the upper electrode, and
a lower surface of the upper electrode has a dent in a central portion.

### (Appendix 2)

The semiconductor device according to appendix 1, wherein the second portion of the insulating film is thicker downward.

### (Appendix 3)

The semiconductor device according to appendix 1 or 2, wherein the upper electrode has a portion in which a side surface is inclined inward of the trench.

### (Appendix 4)

The semiconductor device according to any one of appendixes 1 to 3, wherein the semiconductor layer includes a first semiconductor layer of a first conductive type, and a second semiconductor layer of a second conductive type provided on the first semiconductor layer, the second conductive type being different from the first conductive type, and
among the second portion of the insulating film, a portion adjacent to the first semiconductor layer is thicker than a portion adjacent to the second semiconductor layer.

### (Appendix 5)

The semiconductor device according to any one of appendixes 1 to 4, wherein the third portion is thicker than the second portion.

### (Appendix 6)

The semiconductor device according to any one of appendixes 1 to 5, wherein the first portion is thicker than the second portion.

### (Appendix 7)

The semiconductor device according to any one of appendixes 1 to 6, wherein irregularities on an upper surface of the buried electrode are smaller than irregularities on an upper surface of the upper electrode.

### (Appendix 8)

The semiconductor device according to any one of appendixes 1 to 7, wherein the buried electrode is formed of amorphous silicon.

### (Appendix 9)

The semiconductor device according to any one of appendixes 1 to 8, wherein the semiconductor layer is made with a wide band gap semiconductor.

### (Appendix 10)

The semiconductor device according to appendix 9, wherein the wide band gap semiconductor is silicon carbide, gallium-nitride-based material or diamond.

### (Appendix 11)

A method for manufacturing a semiconductor device, the method comprising:
forming a trench in a semiconductor layer;
forming a buried electrode and a first oxide film that separates the buried electrode from a side wall of the trench, inside the trench;
removing part of the first oxide film so that a portion above the buried electrode, among the first oxide film, has a tapered shape;
forming a second oxide film so as to cover an upper surface of the buried electrode, the side wall of the trench and the portion having the tapered shape; and
forming an upper electrode on the second oxide film inside the trench.

### (Appendix 12)

The method for manufacturing the semiconductor device according to appendix 11, wherein among the second oxide film, a portion between the upper electrode and the side wall of the trench is thicker downward.

In the semiconductor device according to the first disclosure, the lower surface of the upper electrode has a dent in the central portion. This makes it possible to form the third portion of the insulating film that is thick in the central portion of the upper electrode, so that it is possible to reduce gate-emitter capacitance.

In the method for manufacturing the semiconductor device according to the second disclosure, the second oxide film is formed so as to cover the portion having a tapered shape of the first oxide film, and the upper electrode is formed on the second oxide film. This makes it possible to form a portion that is thicker downward between the upper electrode and the side wall of the trench among the second oxide film. It is therefore possible to reduce gate-collector capacitance while preventing increase of a threshold.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2022-156707, filed on Sep. 29, 2022 including specification, claims, drawings and summary, on which the Convention priority of the present application is based, are incorporated herein by reference in its entirety.

1. A semiconductor device comprising:
a semiconductor layer in which a trench is formed;
a buried electrode provided inside the trench;
an upper electrode provided above the buried electrode inside the trench;
an insulating film provided inside the trench;
a first electrode provided on an upper surface of the semiconductor layer; and
a second electrode provided on a lower surface of the semiconductor layer,
wherein the insulating film includes a first portion between the buried electrode and a side wall of the trench, a second portion between the upper electrode and the side wall of the trench, and a third portion between the buried electrode and the upper electrode, and
a lower surface of the upper electrode has a dent in a central portion.

2. The semiconductor device according to claim 1, wherein the second portion of the insulating film is thicker downward.

3. The semiconductor device according to claim 1, wherein the upper electrode has a portion in which a side surface is inclined inward of the trench.

4. The semiconductor device according to claim 1, wherein the semiconductor layer includes a first semiconductor layer of a first conductive type, and a second semiconductor layer of a second conductive type provided on the first semiconductor layer, the second conductive type being different from the first conductive type, and
among the second portion of the insulating film, a portion adjacent to the first semiconductor layer is thicker than a portion adjacent to the second semiconductor layer.

5. The semiconductor device according to claim 1, wherein the third portion is thicker than the second portion.

6. The semiconductor device according to claim 1, wherein the first portion is thicker than the second portion.

7. The semiconductor device according to claim 1, wherein irregularities on an upper surface of the buried electrode are smaller than irregularities on an upper surface of the upper electrode.

8. The semiconductor device according to claim 1, wherein the buried electrode is formed of amorphous silicon.

9. The semiconductor device according to claim 1, wherein the semiconductor layer is made with a wide band gap semiconductor.

10. The semiconductor device according to claim 9, wherein the wide band gap semiconductor is silicon carbide, gallium-nitride-based material or diamond.

11. A method for manufacturing a semiconductor device, the method comprising:
forming a trench in a semiconductor layer;
forming a buried electrode and a first oxide film that separates the buried electrode from a side wall of the trench, inside the trench;
removing part of the first oxide film so that a portion above the buried electrode, among the first oxide film, has a tapered shape;
forming a second oxide film so as to cover an upper surface of the buried electrode, the side wall of the trench and the portion having the tapered shape; and
forming an upper electrode on the second oxide film inside the trench.

12. The method for manufacturing the semiconductor device according to claim 11, wherein among the second oxide film, a portion between the upper electrode and the side wall of the trench is thicker downward.
